(19) United States
(12) Patent Application Publication
(10) Pub. No.: US 2004/0205287 A1
(43) Pub. Date: Oct. 14, 2004

(54) Method, apparatus, and system for quality performance evaluation of a supplier base

(76) Inventors: Steven D. Joder, Maumee, OH (US); David W. Cox, South Whitley, IN (US); Anthony J. Baugh, Ft. Wayne, IN (US)

Correspondence Address: Richard S. MacMillan, MacMillan, Sobanski & Todd, LLC, One Maritime Plaza, Fourth Floor, 720 Water Street, Toledo, OH, 43604, US

(21) Appl. No.: 10/623,478

(22) Filed: Jul. 18, 2003

Related U.S. Application Data
(63) Continuation of application No. PCT/US02/01671, filed on Jan. 18, 2002.
(60) Provisional application No. 60/262,867, filed on Jan. 18, 2001.
(60) Provisional application No. 60/291,443, filed on May 16, 2001.
(60) Provisional application No. 60/339,978, filed on Dec. 10, 2001.

(51) Int. Cl. G11C 5/00

(52) U.S. Cl. 711/1

(57) ABSTRACT

Information regarding the quality of performance of a plurality of suppliers that each supply goods to a vendor is generated by initially gathering data regarding the quality of performance of the plurality of suppliers in a plurality of different computer databases, some of all of which may be incompatible. The gathered data from the plurality of different computer databases is stored in a central controller. Then, the stored data in the central controller converted into a compatible format and stored in a single database. From that single database, information regarding the quality of performance of a plurality of suppliers can be generated.

### CROSS REFERENCE TO RELATED APPLICATION

This application is a continuation of International Application No. PCT/US02/01671, filed Jan. 18, 2002, which claimed the benefit of U.S. Provisional Application No. 60/262,867 filed Jan. 18, 2001, 60/291,443 filed May 16, 2001, and 60/339,978 filed Dec. 10, 2001, the disclosures of all of which are incorporated herein by reference.

### BACKGROUND OF THE INVENTION

This invention relates generally to a method, apparatus, and system for analyzing quality performance of a supplier base.

Over the years, vendors have attempted to meaningfully track, keep record of, and evaluate quality performance information. The primary problems associated with these efforts revolved around the difficulties experienced with effectively, reliably, and efficiently communicating the quality performance information between vendor and supplier.

Traditionally, vendors wishing to monitor supplier quality performance information would gather data from a number of non-compatible computer databases, then manually manipulate the information so as to translate and coordinate the information into a useable format. These attempts to manipulate data and manage and share the data across various platforms, software applications, and user groups have been very time consuming and prone to error. Both time and error frustrations are owed to the fact that the data was “handled” numerous times and by various individuals, all in an attempt to configure the data into a presentable and useable format. The interjection of multiple individuals lead to human error, which resulted in an unrealistic and non-useful view of the true, overall level of quality performance.

Moreover, the particular problems presented by the length of time necessary to produce useable data meant that time sensitive information was only available after a significant delay, which frequently occurred after it was already too late to take corrective action.

Those attempts to manage and share data across various platforms, software applications, and users that have been successful have accomplished their goal by requiring all users to adopt certain uniform practices and procedures. In other words, suppliers would be forced to conform their processes or methodologies in accordance with the needs and requirements of the platform, software, and users employed by the vendors. This solution is undesirable because it forces a multitude of suppliers to modify their current business practices to conform with the vendor. Such conformance, while possible, is indeed costly in terms of the drain placed on human resources.

Furthermore, management and sharing systems have historically suffered from a closed architecture which is difficult to scale, enhance, and/or customize.

### SUMMARY OF THE INVENTION

This invention advantageously fills the aforementioned deficiency in the prior art by providing a method, apparatus, and system for the real time management and sharing of time sensitive information across a variety of platforms, software, applications and users. The invention allows for the collection and transmission of supplier performance information for the management of a supplier base to a vendor. The invention advantageously enables vendors and suppliers to communicate across non-compatible platforms and software applications in real time. The invention accomplishes this goal through the employment of the World Wide Web or other global communication network capable of transmitting and receiving information to and from a remote location. Thus, the invention is unique in that it successfully uses a web-enabled tool designed for “shop floor” statistical process control reporting, such as QualTrend (available from e-WinSPC), to combine data from diverse and non-compatible databases that are not capable of readily exchanging information in a routine and efficient manner, such as Lotus Notes and Oracle databases. Not only is the present invention capable of combining data from diverse, non-compatible databases, but it does so in a manner that allows for the virtual real time reporting of internal manufacturing and supply chain performance. This invention simultaneously takes data from a multitude of databases, some perhaps compatible and some perhaps non-compatible, and processes it using hard coded software to produce the desired evaluations in a near real time environment. To accomplish this, this invention reduces information processing time from days to seconds, automatically extracts existing electronic information, and publishes manipulated data through web-based technology. The efficiencies created by this invention free up resources previously engaged in data gathering, analysis, and manipulation, thereby streamlining quality control and performance evaluation, which provides for a proactive method to initiate corrective action. Aspects of the present invention are directed to a computer program and an apparatus corresponding to the method previously described.

Various objects and advantages of this invention will become apparent to those skilled in the art from the following detailed description of the preferred embodiment, when read in light of the accompanying drawings.

### BRIEF DESCRIPTION OF THE DRAWINGS

FIG. 1 is a block diagram of a system for analyzing quality performance of a supplier base in accordance with this invention.

FIG. 2 is an alternative block diagram of the overall system that shows the application data flow for this invention.

FIG. 3 is a data process flow diagram for this invention.

FIG. 4 is a block diagram of the central controller.

FIG. 4A is an alternative block diagram of the central controller.

FIG. 5 is a block diagram of the supplier terminal.

### DETAILED DESCRIPTION OF THE PREFERRED EMBODIMENT

This invention is directed to a method, apparatus, and system for analyzing quality performance of a supplier base. The preferred embodiment of the present invention: (1) uses information technology (IT) to merge existing, non-compatible databases; and (2) web technologies to simultaneously display information in near real time at a variety of remote locations. In so doing, this invention reduces the time associated with the tabulation and transmission of data from days to seconds and thereby frees up resources previously engaged in data manipulation.

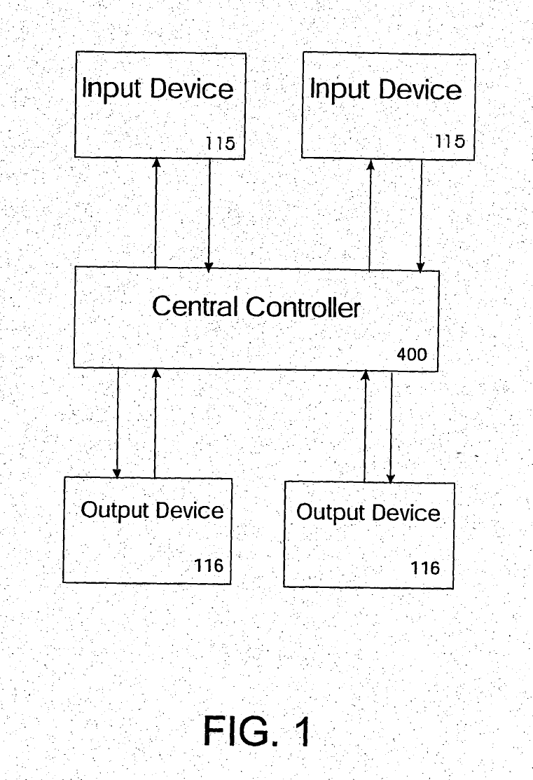

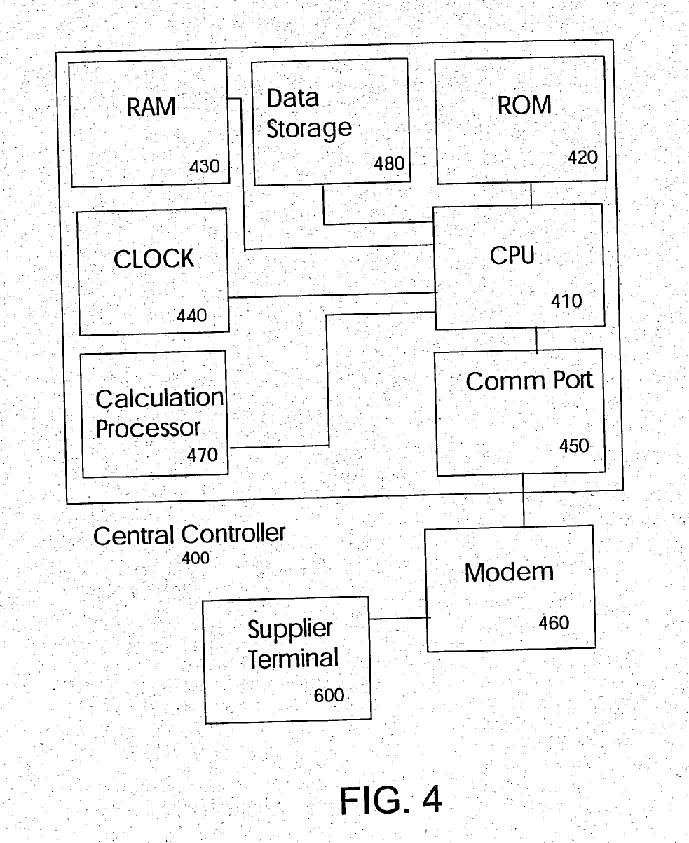

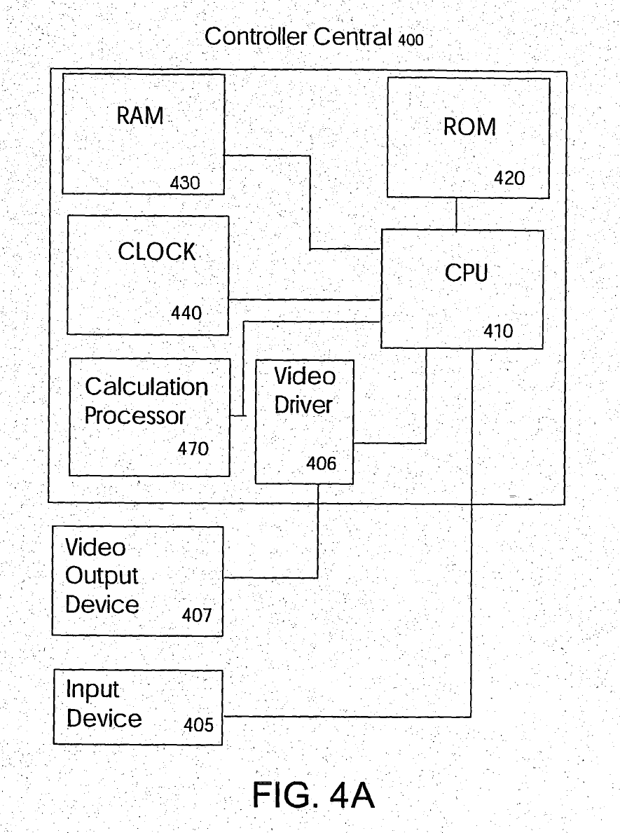

Referring to the drawings, illustrated in FIG. 1 is an overall system block diagram of this invention. In this embodiment, the central controller 400 (described below in connection with FIG. 4) is linked to at least one input device 115. Two input devices 115 are depicted in FIG. 1, but it will be readily understood by those skilled in the art that any number of such input devices 115 may be used. Information can be entered from any one of the multiple input devices 115. The information is passed between the input device 115 and the central controller 400 until the information is received and resident in the central controller 400. The central controller 400 acts as the central brain and is where the information from various non-compatible platforms will be received, translated, and manipulated into useful, compatible quality performance information. The input device 115 may be a supplier terminal 500 (described below in connection with in FIG. 6) including, but not limited to, a keyboard, a mouse, a touch screen, a laser pen, a voice recognition system, a bar code scanner, or any other input device that is capable of collecting information and conveying information to the central controller 400. One of the unique features of this invention is that the various input devices 115 employed need not be homogenous. In other words, a variety of input devices may be used without regard to whether they are identical and without regard to compatibility. The central controller 400 acts as the brain and translates the information that is received into a format that can be displayed by one or more output devices 116. The preferred output device 116 is a computer monitor or other visual display that is connected either directly to a communications medium, preferably a global communications medium such as the Internet. It should, however, be readily apparent to those skilled in the art that any other communications media may and can be employed instead of, or in conjunction with, the global communications medium such as the Internet. Alternative communications media include, but are not limited to, computers networked via satellites, as well as stand alone computer networks.

The system depicted in FIG. 1 may be embodied in hardware specifically provided to implement this invention. Alternatively, the system may be implemented using the equipment and infrastructure already in place and used by suppliers and/or vendors.

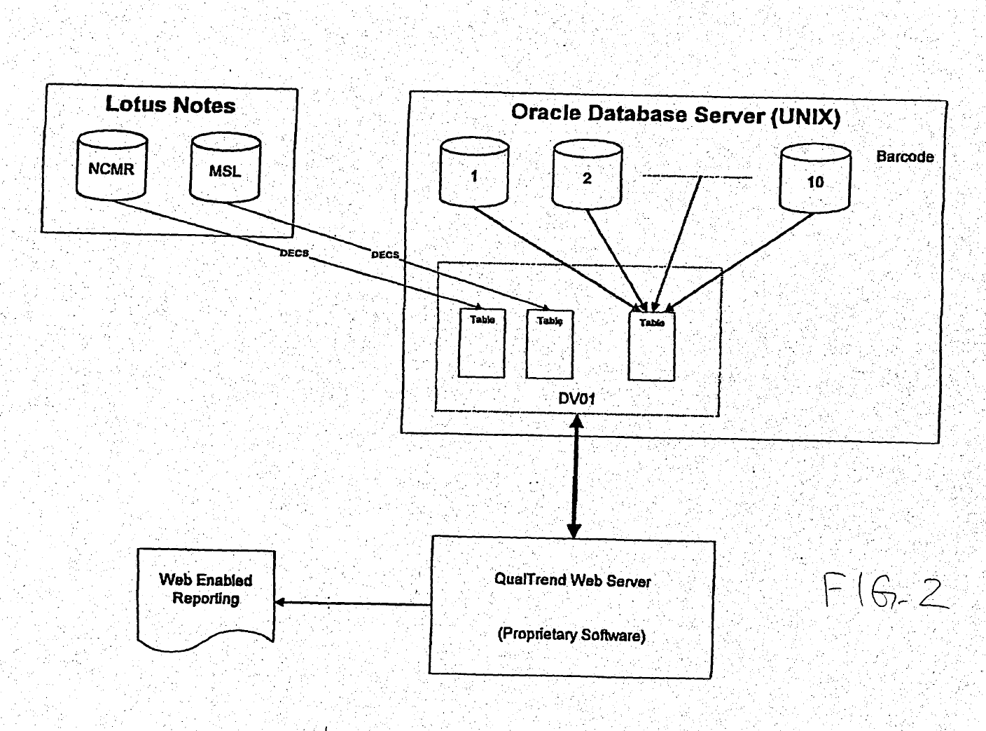

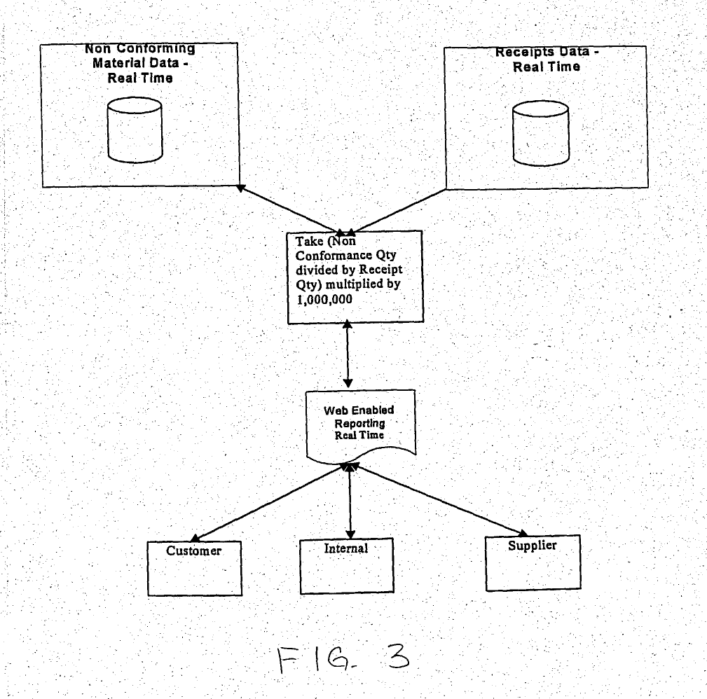

FIG. 2 is an alternative block diagram of the overall system that shows the application data flow for this invention, and FIG. 3 depicts a data process flow diagram for this invention. Nonconforming Material Reports (NCMR) and a Master Supplier List (MSL) constitute databases that are resident in the Lotus Notes application QSi 9000. These databases are updated as NCMRs are initiated and new suppliers are added. The detailed nonconformance information (such as quantity, document trace number, dates, and supplier, for example) is drawn from these databases in a near real time basis. The Oracle database “Barcode” is used to draw part receipt quantity information bar-coded into the system from a plurality of manufacturing facilities across a geographic area (such as a particular region, the entire country, a continent, or the entire world) in a near real time environment.

One of the unique features of this application is the use of a common table to store the NCMR, Supplier, and Part Receipt data. The Lotus Notes information is transferred to the table using the Lotus Notes utility Domino Enterprise Connecting Services (DECS). Specific part and plant information is transferred from the Oracle “Barcode” database to the common table in a near real time environment.

Another unique feature of this system is the use of a web enabled tool designed for “shop floor” statistical process control reporting software, such as QualTrend (available from e-WinSPC), for this particular information processing. The application is designed for reporting of shop floor Statistical Process Control (SPC) data gathered manually or electronically from machine programmable logic controllers (PLC). In this instance, the statistical process control reporting software is used to process the data gathered in the common table residing on the Unix Server to create a series of quality metrics used in judging the performance of a single supplier or the performance of a group of suppliers. The display of the metrics is accomplished through “hard coding” the data using proprietary software, such as the QualTrend (e-WinSPC). It will be readily apparent to those skilled in the art that QualTrend (e-WinSPC) is not the only proprietary software capable of displaying the metrics.

The parts per million defects (PPM) and number of corrective actions (CARs) are displayed by the supplier and by the manufacturing plant(s) that the supplier serves. The data can be presented in any desired time frame, such as yearly, quarterly, monthly, weekly, daily, hourly, and/or by the minute. Additionally, the system has the unique ability to “drill down” from any of the tables to the original rejection document (NCMR) at the click of a mouse. This near real time capability makes problem identification virtually immediate and provides the opportunity for proactive initiation of corrective action, which is the primary goal of the present invention.

The PPM application can be accessed through a customized web portal. The PPM application displays defects per million information for plants owned or operated by end users of the PPM application that are supplying customers and for plants owned by suppliers that are providing the products. Data sources can include conventional software applications and databases that existed prior to the development of the PPM application. Customized queries can be written to extract data from existing data sources and display PPM information via a web browser or similar software application and/or visual display means.

The PPM application uses a color-coding scheme to display how well plants that are owned or operated by the owner of the application and suppliers thereto conform to targeted quality defect levels. Defect levels within a first range (such as, for example, less than 349 defects per million) can be displayed in a first color (such as green), defect levels within a second range (such as, for example, between 350 and 550 defects per million) can be displayed in a second color (such as yellow), and defect levels within a third range (such as, for example, above 500 defects per million) can be displayed in a third color (such as red). These ranges may be varied as desired in order to meet the needs and expectations of the various suppliers and vendors using the application. Summary information for a vendor or supplier can also be displayed as desired. Drill-down capabilities can be provided to display individual suppliers and vendors across pre-determined time frames (e.g., yearly, quarterly, and weekly, for example).

The application can also display individual Non-Conforming Material Reports (NCMRs), Corrective Action Reports (CARs), digital photographs of the defective parts, and on-time delivery statistics for areas where this data is currently being collected.

The PPM application can further include enhancements, such as (1) configuration parameters (e.g., modified color-coded cut-off points and alert points), (2) standardized connections to standard quality applications and databases, (3) data entry into an additional data source for locations currently not collecting required data, (4) drill down capabilities to the individual parts and transactions that created the summary views, (5) security to allow limited access to the data, (6) reporting capabilities beyond display via a web browser, (7) ability to determine if a supplier is improving over time (i.e., showing trends and variability), (8) documentation to support installation, training, and technical support, (9) ability to generate vendor scorecards based on configurable parameters, and (10) provide information about characteristics such as quality versus cost and quality versus lead-time.

The intent of the web portal is to provide simultaneous and near real time access to quality performance data through a single point of entry. The preferred embodiment provides access to quality performance data via a software application resident on a computer, such as a commonly available web browser. Via a web browser, the application displays defects per million information for manufactured items delivered to customers of the vendor and for manufactured items provided from suppliers. The power of the PPM application is its ability to quickly and easily display to decision makers quality defect information from customers and suppliers via a single and simple point of entry using a web browser or other similar software application and/or visual display means. The application queries current data sources from various locations, which may be non-compatible. The PPM application then translates the data into useable form and then displays the quality defect information. Current data sources can include databases that the customers and suppliers are currently using, including Oracle databases and Lotus Notes.

The PPM application uses a color-coding scheme to identify the current quality situation with customers and suppliers. For example, if a manager is interested in quality data of parts supplied to customers, the application displays the customer names and time periods in a tabular format. If the PPM calculation for a customer and time period is “good”, a cell is displayed in green. Other colors are yellow (for caution) and red (for bad). Green can be displayed if the PPM calculation is less than 349 defects per million. Yellow can be displayed for defects per million between 350 and 500. Red can be displayed for defects per million of over 500. The PPM application can display PPM data over a specified time frame (e.g., one year), but also possesses the capability to “drill down” the time periods into small time units (e.g., quarters, months, or weeks, for example). Drill down capabilities are also available for each customer name to display the manufacturing facility supplying the customer. Drill downs are achieved via a simple click of the mouse on the customer name. These “targeted” cutoffs set at green for less than 349 defects per million, yellow for between 350 and 500 defects per million, and red for greater than 500 defects per million can be configured as desired.

The OEM's inspect parts delivered from the owner of the application to their plants. Information about defects is sent back to the manufacturing plant and entered into quality applications at the plant. The PPM application queries the existing quality applications and displays the customer defect information via a web browser. The data is displayed in a tabular format by plant to each customer over pre-determined time frames. To obtain data from customers in a more responsive manner, the use of XML files from customers can be used.

The PPM application also displays defect information from suppliers to the owner of the application. Initially, the suppliers are displayed, and can be sorted from suppliers with the most defects per million to least defects per million. Drill down capabilities for each supplier is available by clicking on the supplier name. Supplier's quality data can be seen in a tabular format by various time periods (yearly, quarterly, weekly, etc.) and plants. The same color-coding scheme is employed for supplier data display as customer data display (e.g., green, yellow, and red).

The data source for displaying supplier quality data can include existing quality systems that are populated when products are received from the suppliers. If the owner of the application collects and stores more quality performance data relative to parts received from suppliers that they get returned from customers, this additional information can be easily displayed via the PPM application. From the supplier side, managers can retrieve PPM data by supplier/plant/timeframe, can display Non-Conforming Material Reports (NCMRs), can display Corrective Action Reports (CARs), and can display digital photographs of the defective parts, in JPEG or GIF format or other similar file format appropriate for viewing via a web browser. Given the proper access, customers and suppliers of the owner of the application can also view this information via a web browser giving the potential for advanced collaboration to more proactively and more quickly solve part defect issues.

In addition to quality data, the application is also capable of displaying data relating to on-time deliveries. The power of the application rests in its ability to create a dashboard environment for managers to very easily and quickly ascertain quality data from suppliers and customers. A very easy to use web-based front end that queries disparate systems provides this. Technical architecture is also simplified due to the fact that users need only a web browser installed on their computer to use the application (with the proper network connection).

Technically, the application queries existing disparate data sources and displays the data in an understandable manner. The concept is very powerful if managed properly across the supply chain. This application can enable customers and suppliers to take a more proactive position regarding defective product shipped from supplier to customer by providing quality data in a more timely, easily understood and easily accessible format. If a more proactive approach is actually taken, savings can result in minimizing re-work, transportation of defective product, and the tracking and administration of defective product. The application could be extended to quantify these savings by making some assumptions about the costs of these activities.

FIG. 4 is a block diagram of a central controller 400. The central controller includes a central processing unit (CPU) 410, which is responsible for performing the processing functions of the central controller 400. The central controller 400 also includes a Read Only Memory (ROM) 420 and a Random Access Memory (RAM) 430. The ROM 420 is used to store at least some of the program instructions that are to be executed by the CPU 410, such as portions of the operating system or basic input-output system (BIOS), and the RAM 430 is used for temporary storage of data. A clock circuit 440 provides a clock signal that is required by the CPU 410 in order to adequately perform its functions. The central controller 400 may also include a conventional calculation processor 470 that is connected to the CPU 410. The use of a CPU 410 in conjunction with ROM 420, RAM 430, and a clock circuit 440 should be well known to those skilled in the art of computer hardware design.

The central controller 400 also includes a communications port 450 that enables the CPU 410 to communicate with external devices, such as a supplier terminal 600. The communications port 450 enables communication between external devices and the CPU 460 through a modem 460. It should be noted that while the illustrated embodiment depicted in FIG. 4 uses a modem 460 to communicate with remote devices, it should be readily known and well understood to those educated in the art that other methods of communicating with remote devices may be used instead of, or in conjunction with, a modem. The CPU 410 can also store information to and read information from a data storage device 480.

FIG. 4A is an alternative embodiment of a central controller 400. FIG. 4 depicts an input device 405 that is connected directly to the CPU 410 of the central controller. This input device may be a keyboard, a voice recognition system, or any other device that is capable of communicating information from the user to the central controller 400. Additionally, FIG. 4 depicts a video output device 407, which is connected to the CPU 410 through a video driver 406.

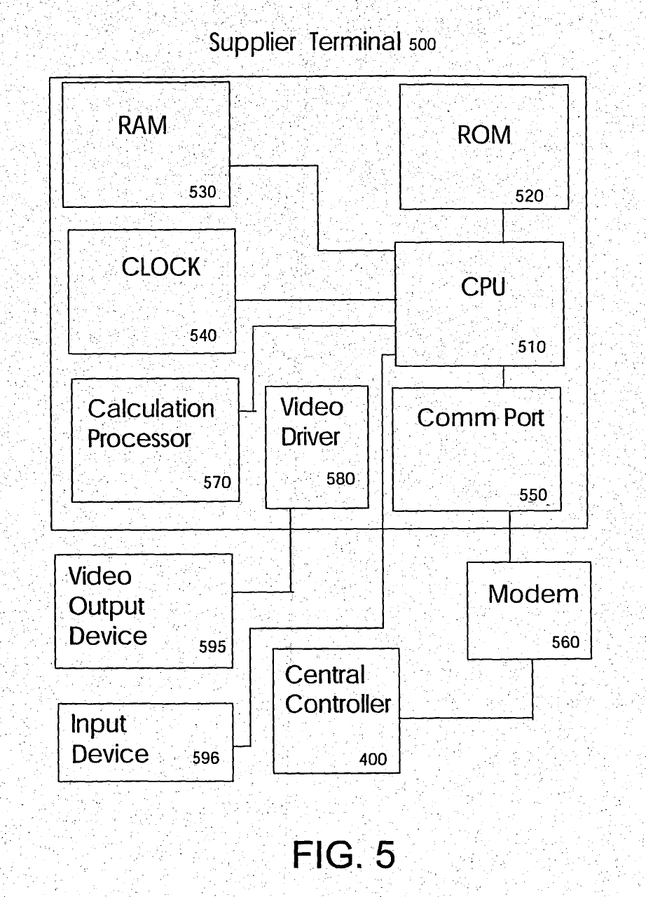

FIG. 5 is a block diagram of a supplier terminal 500, which can be located at any number of locations, including but not limited to a supplier's office, a warehouse, or a factory. There can be any number of supplier terminals 500 linked up to one central controller 400. Like the central controller 400 described above, the supplier terminal 500 includes a CPU 510, a ROM 520, a RAM 530, and a clock circuit 540. The supplier terminal 500 also includes a communications port 550 that connects to a modem 560 or other communications device to enable communication between the supplier terminal 500 and the central controller 400. It is also possible for either an IBM compatible personal computer or an Apple Macintosh computer to be used as the supplier terminal. Alternatively, a dedicated, stand-alone supplier terminal may be used.

The supplier terminal 500 also includes an input device 596 to receive input from an operator. Any of a wide variety of input devices would be suitable for this purpose, including but not limited to a keyboard, a mouse, a touch screen, a laser pen, a voice recognition system, a bar code scanner, or any other input device capable of collecting and transmitting information. The input device 596 can interface directly with the CPU 510. Alternatively, an appropriate interface circuit may be placed between the CPU 510 and the input device 596.

The supplier terminal 500 also includes a video output device 595 for conveying information to the operator. The preferred embodiment of the video output device 595 is a computer monitor. However, there are a number of other appropriate video output devices that are capable of visually displaying the necessary information to the operator. A video driver 580 is also necessary to enable the CPU 510 to connect with the video output device 595. The supplier terminal 500 also includes a conventional calculation processor 570 in which the calculation processor instructions are stored. These instructions can be read by and executed by the CPU 510, thus enabling the CPU 510 to process transactions.

In accordance with the provisions of the patent statutes, the principle and mode of operation of this invention have been explained and illustrated in its preferred embodiment. However, it must be understood that this invention may be practiced otherwise than as specifically explained and illustrated without departing from its spirit or scope.

What is claimed is:

1. A method of generating information regarding the quality of performance of a plurality of suppliers that each supply products to a vendor, said method comprising the steps of:
(a) gathering data regarding the quality of performance of the plurality of suppliers in a plurality of different computer databases;
(b) storing the gathered data from the plurality of different computer databases in a central controller;
(c) converting the stored data in the central controller into a single database; and
(d) utilizing the single database to generate information regarding the quality of performance of the plurality of suppliers.

2. The method defined in claim 1 wherein said step (a) is performed by gathering data regarding the quality of performance of the plurality of suppliers in a plurality of different computer databases that are non-compatible.

3. The method defined in claim 2 wherein said step (c) is performed by converting the stored data in the central controller into a single compatible database.

4. The method defined in claim 1 wherein said step (a) is performed by gathering data regarding the quality of performance of the plurality of suppliers in real time.

5. The method defined in claim 4 wherein said step (b) is performed by storing the gathered data from the plurality of different computer databases in a central controller in near real time.

6. The method defined in claim 5 wherein said step (c) is performed by converting the stored data in the central controller into a single database in near real time.

7. The method defined in claim 6 wherein said step (d) is performed by utilizing the single database to generate information regarding the quality of performance of the plurality of suppliers in near real time.

8. The method defined in claim 1 wherein said step (d) is performed by processing the stored data in the single database to create a series of quality metrics and using the series of quality metrics to judge the performance of one or more of the plurality of suppliers.

9. The method defined in claim 1 wherein said step (d) is performed by generating the information on a global communication network.

10. The method defined in claim 9 wherein said step (d) is performed by providing access to the information on the global communication network to each of the plurality of suppliers.

11. The method defined in claim 10 wherein said step (d) is performed by providing limited access to the information on the global communication network to each of the plurality of suppliers.

12. The method defined in claim 11 wherein said step (a) is performed by displaying the information on an internet web browser.

13. The method defined in claim 1 wherein said step (d) is performed by using a color-coding scheme to display the generated information.

14. The method defined in claim 1 wherein said step (a) is performed by generating a non-conforming material report whenever a defective product is supplied to the vendor.

15. The method defined in claim 14 wherein said step (d) is performed by transmitting the non-conforming material report to the supplier.

16. The method defined in claim 14 wherein said step (d) is performed by requesting a corrective action report from the supplier whenever a non-conforming material report is generated.
